(19) United States
(12) Patent Application Publication
(10) Pub. No.: US 2015/0091031 A1
(43) Pub. Date: Apr. 2, 2015

(54) LOCATING OPTICAL STRUCTURES TO LEDS

(71) Applicant: GOODRICH CORPORATION, Charlotte, NC (US)

(72) Inventor: Gerald B. Biehle, Phoenix, AZ (US)

(21) Appl. No.: 14/041,874

(22) Filed: Sep. 30, 2013

(51) Int. Cl. H01L 33/48; H01L 33/60; H01L 33/62; H01L 33/58

(52) U.S. Cl. CPC H01L 33/486; H01L 33/58; H01L 33/60; H01L 33/62; H01L 2933/0033; H01L 2933/0066; H01L 2933/0058
USPC 257/98; 438/27

(57) ABSTRACT

An optical device and a method of making an optical device are disclosed. A printed wiring board is formed that includes coupling elements at selected locations. The coupling elements are formed using a printed wiring board manufacturing technique. A light source may be coupled to the printed wiring board at one of the coupling elements. An optical structure for directing light from the light source may be coupled to the printed wiring board at another coupling element. A tolerance for a distance between the optical structure and the light source is thus controlled using the manufacturing technique.

### BACKGROUND

Various mechanical parts, such as airplane parts, employ light sources that are integrated into a printed wiring board. The printed wiring board is then generally secured to the mechanical part or other machined part which may include optical structures for directing the light from the light sources of the printed wiring board. The optical structures often need to be placed close to these light sources with high positional precision. For example a reflector located on the mechanical part may need to be located very precisely relative to the light source. Such precision is difficult to obtain when the light source and optical structures are on separate parts.

### SUMMARY

According to one embodiment of the present invention, a method of making an optical device includes: forming coupling elements at selected locations on a printed wiring board using a printed wiring board manufacturing technique; coupling a light source to the printed wiring board at one of the coupling elements; and coupling an optical structure to the printed wiring board at another of the coupling elements at a selected distance to the light source, wherein a tolerance for the selected distance is controlled using the printed wiring board manufacturing technique.

According to another embodiment, an optical device includes: a printed wiring board having a first coupling element and a second coupling element formed thereon using a printed wiring board manufacture technique; a light source coupled to the printed wiring board at the first coupling element; and an optical structure coupled to the printed wiring board at the second coupling element, wherein a tolerance of a distance between the optical structure and the light source is controlled via the manufacturing technique.

Additional features and advantages are realized through the techniques of the present invention. Other embodiments and aspects of the invention are described in detail herein and are considered a part of the claimed invention. For a better understanding of the invention with the advantages and the features, refer to the description and to the drawings.

### BRIEF DESCRIPTION OF THE SEVERAL VIEWS OF THE DRAWINGS

The subject matter which is regarded as the invention is particularly pointed out and distinctly claimed in the claims at the conclusion of the specification. The forgoing and other features, and advantages of the invention are apparent from the following detailed description taken in conjunction with the accompanying drawings in which:

FIG. 1 shows an illustrative optical device that may be formed using the method disclosed herein;

FIG. 2 shows another optical device that may be formed using the methods disclosed herein;

FIG. 3 shows a cross-section of a slot and a hole formed in a part attached to the optical device of FIG. 2; and

FIG. 4 shows a flowchart of an illustrative method of the present invention for making an optical device using the methods disclosed herein.

### DETAILED DESCRIPTION

Various printed wiring boards, i.e., circuit boards, include light sources, such as light emitting diodes (e.g., LEDs) that provide a light when activated. Optical structures such as lenses, reflective surfaces, etc., are generally secured at selected locations with respect to the light sources in order to reflect or divert the light or perform other optical functions. The present invention places such optical structures on the same printed wiring board as the light sources and close to the light sources. When these optical structures and their related light sources are at such close distances, spatial tolerances of 1/1000 of an inch are generally demanded. Such tolerances are difficult to obtain using known methods. However, these tolerances are routinely achieved in the manufacture of printed wiring boards and the electrical components that are formed during such manufacture, such as semiconductors, transistors, circuit wires, etc. Exemplary manufacturing techniques may include lithography, photoetching, plating techniques, etc. Therefore, using these manufacturing techniques, the present invention forms structures on the printed wiring board that may be used to place optical structures and light sources at separation distances that are within a selected tolerance.

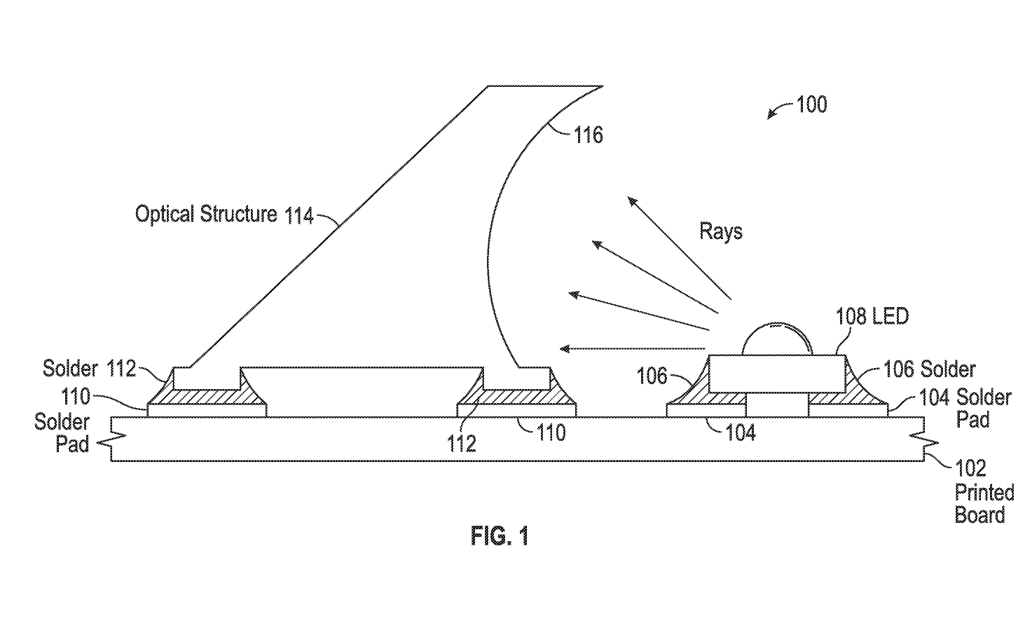

FIG. 1 shows an illustrative optical device 100 that may be formed using the method disclosed herein. The optical device 100 includes a printed wiring board 102 that includes solder pads 104 and 110 that may be formed thereon using manufacturing techniques such as lithography, photoetching, plating techniques, etc. In an exemplary embodiment, material for the solder pad may be deposited on the printed wiring board 102, and a mask may then be applied to the material. The mask may include a design for determining the locations of the solder pads 104 and 110. The design may be transferred to the solder pad material using for instance photoetching techniques and the solder pads 104 and 110 may thus be formed. The locations of the solder pads 104 and 110 on the printed wiring board 102 may therefore be controlled to within a selected tolerance. In an exemplary embodiment, this tolerance is within 1/1000 of an inch.

Light source (e.g., LED) 108 is coupled to the solder pads 104. In one embodiment, a selected amount or selected volume of solder 106 is chosen for soldering the light source 108 to the solder pads 104. Similarly, optical structure 114 is coupled to solder pad 110 using a selected volume of solder 112. Surface tension of the solder 106, 112 while heated to a liquid state allows for self-centering of the optical structure 114 and the light source 108, thereby increasing a relative positional precision of the optical structure 114 and the light source 108 once the solder has cooled. The illustrative optical structure 114 includes a reflective surface 116 that is shaped so as to reflect the light from the light source 108 according to a manufacturer's specification. Because the printed wiring board manufacturing techniques (such as those used to form circuit elements, semiconductors, transistors, circuit wires, etc.) are used to form the solder pads 104 and 110, the distances between light source 108 and optical structure 114 may be controlled within a tolerance attainable using such techniques, which is a more rigorous tolerance than is generally required for the particular optical set-up. Thus, the light from the light source 108 may be reflected by the optical structure 114 to meet manufacturing specifications. Additionally, the relative closeness of the optical structure 114 to the light source 108 allows reduced size, mass and moment of inertia of the optical structures 114 as compared to an optical structure that is away from the light source and/or off the printed wiring board.

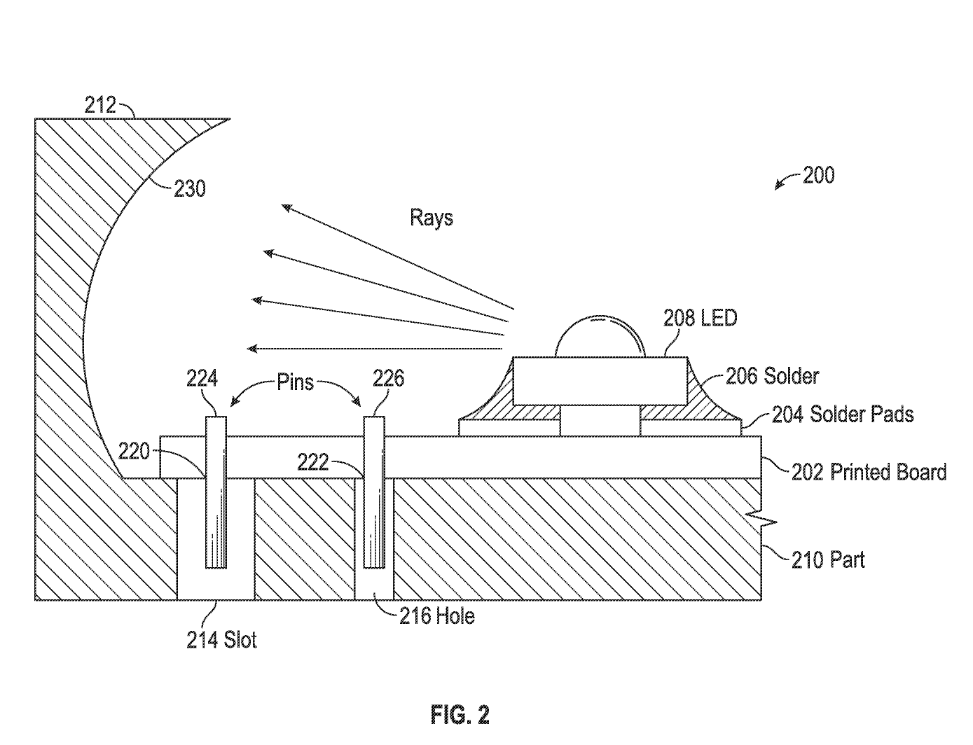

FIG. 2 shows another illustrative optical device 200 that may be formed using the methods disclosed herein. For larger optical structures for which solder is an insufficient mechanical attachment technique, pins may be located in the printed wiring board 202. Mating holes and slots for these pins may be located in a separate optical structure. Alignment of the pins with the mating holes may position he optical structure relative to the light source to within an acceptable tolerance.

In FIG. 2, printed wiring board 202 is coupled to or mechanically attached to part 210 that includes an optical structure 212 formed thereon, The illustrative optical structure 212 includes a reflective surface 230 that is placed at a selected distance with respect to light source 208 once the printed wiring board 202 is coupled to the part 210.

The printed wiring board 202 includes solder pads 204 formed thereon using any of the printed wiring board manufacturing techniques disclosed herein. The printed wiring board 202 also includes holes 220 and 222 formed using these same manufacturing techniques. The light source 208 is soldered to the solder pads 204 using a selected amount of solder 206 using the techniques described above for self-centering. Holes 220 and 222 of the printed wiring board 202 are aligned with slot 214 and hole 216, respectively, of part 210. Pin 224 is inserted into hole 220 and slot 214. Pin 226 is inserted into hole 222 and hole 216. The pins 224 and 226 may thus secure the printed wiring board 202 to the part 210. The pins 224 and 226 may be pins, screws, nails, rivets or any other suitable device for securing the printed wiring board 202 and part 210. Once the part 210 is secured to the printed wiring board 202, the surface 230 of optical structure 212 is positioned at a suitable distance with respect to light source 208, where the distance is within a tolerance suitable for the optical structure to reflect or otherwise direct light from the source according to specifications.

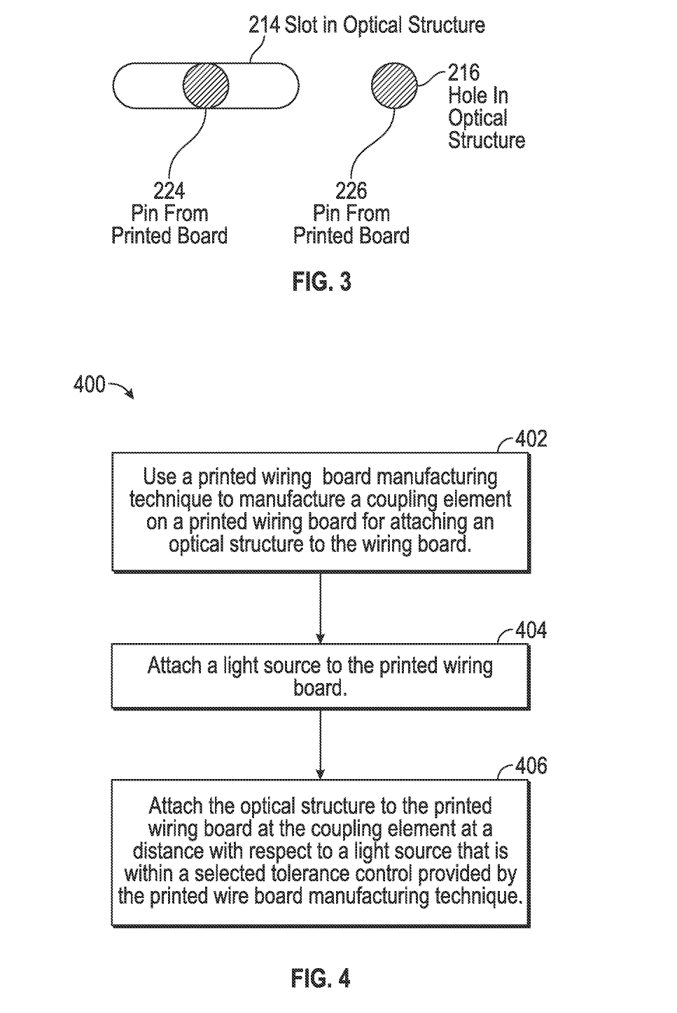

FIG. 3 shows a cross-section of the slot 214 and the hole 216 formed in part 210. Slot 214 is shown to include pin 224 and may allow for play or alignment of hole 220 of the printed wiring board 202 with respect to the part 210 prior to fastening the printed wiring board 202 to the part 210. Hole 216 may be of a same circumferential contour as the pin, thereby allowing a snug fit between the pin 226 and the hole 216.

FIG. 4 shows a flowchart 400 of an illustrative method of the present invention for making the optical device using the methods disclosed herein. In block 402, a technique for manufacturing a printed wiring board and its circuit elements are used to form coupling elements on the printed wiring board for securing an optical structure to the printed wiring board. The coupling element may include solder pads and/or holes. In block 404, a light source is secured to the printed wiring board. In block 406, the coupling element is used to secure an optical structure to the printed wiring board at a distance with respect to the light source that is within a selected tolerance due to the use of the selected manufacturing technique used in forming the coupling element.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated

While the preferred embodiment to the invention had been described, it will be understood that those skilled in the art, both now and in the future, may make various improvements and enhancements which fall within the scope of the claims which follow. These claims should be construed to maintain the proper protection for the invention first described.

What is claimed is:

1. A method of making an optical device, comprising:
forming coupling elements at selected locations on a printed wiring board using a printed wiring board manufacturing technique;
coupling a light source to the printed wiring board at one of the coupling elements; and
coupling an optical structure to the printed wiring board at another of the coupling elements at a selected distance to the light source, wherein a tolerance for the selected distance is controlled using the printed wiring board manufacturing technique.

2. The method of claim 1, wherein a selected coupling element further comprises a solder pad and wherein coupling one of the light source and the optical structure to the printed wiring board further comprises soldering the one of the light source and the optical structure to the printed wiring board at the solder pad.

3. The method of claim 2 further comprising applying a selected volume of solder between the one of the optical structure and the light source and the solder pad to provide self-centering of the one of the optical structure and the light source during a soldering process.

4. The method of claim 1, wherein a selected coupling element further comprises a hole, the method further comprising securing the printed wiring board to a part that includes the optical structure by aligning the hole of the printed wiring board with a hole in the part.

5. The method of claim 1, wherein the printed wiring board manufacturing technique further comprises at least one of: a lithographic technique; a photoetching technique; a plating technique; and a technique used in semiconductor fabrication.

6. The method of claim 1 wherein the light source is a light emitting diode.

7. The method of claim 1, wherein the optical structure is at least one: of a reflective surface; a light shield; and a lens.

8. An optical device, comprising:
a printed wiring board having a first coupling element and a second coupling element formed thereon using a printed wiring board manufacture technique;
a light source coupled to the printed wiring board at the first coupling element; and
an optical structure coupled to the printed wiring board at the second coupling element, wherein a tolerance of a distance between the optical structure and the light source is controlled via the manufacturing technique.

9. The optical device of claim 8, wherein at least one of the first coupling element and the second coupling element comprises a solder pad.

10. The optical device of claim 9 further comprising solder between the solder pad and the one of the optical structure and the light source, wherein a volume of the solder is selected to provide self-centering of the one of the optical structure and the light source during the soldering process.

11. The optical device of claim 8, wherein the coupling element further comprises a hole and the printed wiring board is secured to a part that includes the optical structure by alignment of the hole of the printed wiring board with a hole in the part.

12. The optical device of claim 8, wherein the manufacturing technique of the printed wiring board further comprises at least one of: a lithographic technique; a photoetching technique; a plating technique; and a technique used in semiconductor fabrication.

13. The optical device of claim 1 wherein the light source is a light emitting diode.

14. The optical device of claim 1, wherein the optical structure is at least one: of a reflective surface; and light shield; and a lens.
